(19) United States
(12) Patent Application Publication
(10) Pub. No.: US 2014/0022752 A1
(43) Pub. Date: Jan. 23, 2014

(54) CIRCUIT BOARD SYSTEM

(71) Applicant: Markus Wille, Boenen (DE)

(72) Inventor: Markus Wille, Boenen (DE)

(21) Appl. No.: 13/599,937

(22) Filed: Aug. 30, 2012

(30) Foreign Application Priority Data
Aug. 30, 2011 (DE) 10 2011 111 488.6

(51) Int. Cl. H05K 1/14; H05K 3/36

(52) U.S. Cl. CPC H05K 1/142; H05K 3/36
USPC 361/792; 29/830

(57) ABSTRACT

Disclosed herein is a circuit board system comprising a carrier circuit board which is essentially planar at least in sections, wherein the carrier circuit board has at least one rigid layer copper clad on one or both sides or provided with conductor tracks, wherein at least one essentially planar circuit board module aligned in parallel with the carrier circuit board is arranged with at least one rigid layer copper clad on one or both sides or provided with conductor tracks, in an associated recess in the carrier circuit board. In particular, the circuit board module is pressed into the recess in the carrier circuit board and the edge of the circuit board module is engaged in a friction-locked manner with the edge of the associated recess to form a press fit.

### CROSS-REFERENCE TO RELATED APPLICATIONS

This application claims the benefit of German Patent Application No. DE 10 2011 111 488.6, filed Aug. 30, 2011 in the name of Schoeller-Electronics GmbH, the disclosure of which is incorporated by reference herein in its entirety.

### FIELD OF THE INVENTION

The invention relates to a circuit board system comprising a carrier circuit board which is essentially planar at least in sections, and a method for the assembly of such a circuit board system.

### BACKGROUND OF THE INVENTION

Currently, a circuit board regularly consists of a number of rigid layers of fibreglass-reinforced cured epoxy resin plates which are copper clad on one or both sides or provided with conductor tracks. The circuit board is equipped with semiconductor components, with connecting elements, with elements for heat dissipation or the like.

In the sense of a modular structure, it has become known to provide a circuit board system with a plane carrier circuit board in which at least one circuit board module is arranged (DE 10 2004 019 431 A1). In this context, the at least one circuit board module aligned in parallel with the carrier plate is arranged in a recess in the carrier circuit board.

The problem in the above circuit board system is always that of fixing the circuit board module in the associated recess. Known measures for fixing are in this case bonding, soldering or the like. These measures are expensive to implement.

### SUMMARY OF THE INVENTION

The invention is based on the problem of designing and developing the known circuit board system in such a manner that fixing the circuit board module in the recess associated with the circuit board module is simplified.

The above problem is solved in a circuit board system that includes a carrier circuit board which is essentially planar at least in sections, wherein the carrier circuit board has at least one rigid layer copper clad on one or both sides or provided with conductor tracks, wherein at least one essentially planar circuit board module aligned in parallel with the carrier circuit board is arranged with at least one rigid layer copper clad on one or both sides or provided with conductor tracks, in an associated recess in the carrier circuit board. In particular, the circuit board module is pressed into the recess in the carrier circuit board and the edge of the circuit board module is engaged in a friction-locked manner with the edge of the associated recess to form a press fit.

One factor is the consideration that the mechanical stability of carrier circuit board and circuit board module is regularly sufficient for implementing a press fit for the circuit board module.

Correspondingly, it is proposed that the circuit board module is pressed into the recess in the carrier circuit board associated with the circuit board module and that the edge of the circuit board module is engaged in a friction-locked manner with the edge of the associated recess to form a press fit.

Another factor is that the arrangement is constructed in such a manner that pressing the circuit board module in with a pressing force which is essentially aligned perpendicularly to the flat side of the circuit board module is possible.

In one embodiment, the friction lock is essentially aligned in parallel with the plane of the carrier circuit board.

With a suitable design, the press fit of the circuit board module is adequate for fixing it in the carrier circuit board. Fixing the circuit board module cannot be implemented with less expenditure.

In one embodiment, the press fit holds the circuit board module in the recess in the carrier circuit board. In one embodiment, the circuit board module engages with the associated recess in a friction-locked manner at least in sections, preferably completely. In another embodiment, the circuit board module and the carrier circuit board are arranged essentially in one plane, preferably that the circuit board module and the carrier circuit board end flush, particularly on both sides. In one embodiment, the cross-sectional profile of the edge of the circuit board module and the cross-sectional profile of the edge of the associated recess are matched to one another to form a positive lock. In one embodiment, the cross-sectional profile of the edge of the circuit board module and/or the cross-sectional profile of the edge of the associated recess forms or form at least one peripheral web and/or at least one peripheral groove. In one embodiment, the outer contour of the edge of the circuit board module and the inner contour of the edge of the associated recess are matched to one another to form a positive lock. In one embodiment, the outer contour of the edge of the circuit board module and/or the inner contour of the edge of the associated recess has or have a periodically repetitive structure, particularly a toothed, serrated or waved structure. In one embodiment, the edge of the circuit board module and/or the edge of the recess is or are at least partially metalized. In one embodiment, the circuit board module is designed differently from the carrier circuit board with regard to the material composition and/or surface property and/or layer structure and/or number of layers and/or board thickness. In one embodiment, the carrier circuit board and/or the circuit board module is or are designed as rigid/flexible circuit board. In one embodiment, a flexible section of the circuit board module extends over the edge of the associated recess in the carrier circuit board. In one embodiment, an electrical contact-connection between the carrier circuit board and the circuit board module is provided, preferably that the electrical contact-connection is established by inserting the circuit board module into the associated recess.

In one embodiment, the carrier circuit board has at least one elastic area in the area of the recess, the elastic restoring force of which acts on the circuit board module, preferably in that the at least one elastic area, for increasing the elastic resilience, has at least one weakening of material, especially at least one recess or at least one through-contact arrangement in the carrier circuit board.

According to the invention, the circuit board module can be designed to be different from the circuit board carrier in any regard. This makes it possible to achieve considerable cost savings in the production of the circuit board system, for example in that costly materials are used only where they are absolutely necessary.

In one embodiment, the circuit board module can be removed from the recess and subsequently inserted again. This can simplify any possible maintenance work. In a more specific embodiment, the circuit board module can be removed from the recess by applying a disengaging force and subsequently pressed into the recess again by forming the press fit.

Another embodiment provides a method for the assembly of a circuit board system. In particular, the invention provides a method for the assembly of a circuit board system comprising an at least sectionally essentially planar carrier circuit board, wherein the carrier circuit board has at least one rigid layer copper clad on one or both sides or provided with conductor tracks, wherein at least one essentially planar circuit board module aligned in parallel with the carrier circuit board having at least one rigid layer copper clad on one or both sides or provided with conductor tracks is arranged in an associated recess in the carrier circuit board. In particular, the circuit board module is pressed into the recess in the carrier circuit board and, during this process, the edge of the circuit board module is engaged with the edge of the associated recess in a friction-locked manner to form a press fit.

In one embodiment, the circuit board module is pressed into the recess in the carrier circuit board and that, in this process, the edge of the circuit board module is engaged in a friction-locked manner with the edge of the associated recess to form a press fit.

In the method of the invention, the fact is particularly advantageous that the method step of inserting the circuit board module into the recess in the carrier circuit board can be implemented in a particularly simple manner.

In one embodiment, the circuit board module is clipped into the recess of the carrier circuit board so that the pressing-in force during the insertion of the circuit board module passes through a steep maximum. In this context, the fact is advantageous, among other things, that a predefined and reproducible pressing-in depth is maintained by the clipping-in.

### BRIEF DESCRIPTION OF THE FIGURES

In the text which follows, the invention will be explained in greater detail by means of a drawing only showing illustrative embodiments. In the drawings:

FIG. 1 shows a circuit board system according to the invention a) with a disassembled circuit board module and b) with an assembled circuit board module, in each case in a perspective representation.

FIG. 2 shows, a) a further circuit board system according to the proposal with disassembled circuit board module in a perspective view, b) a further circuit board system according to the proposal with disassembled circuit board module in a sectional view, c) a further circuit board system according to the proposal with disassembled circuit board module in a sectional view.

FIG. 3 shows a further circuit board system according to the proposal with disassembled circuit board module in a perspective representation.

### DETAILED DESCRIPTION

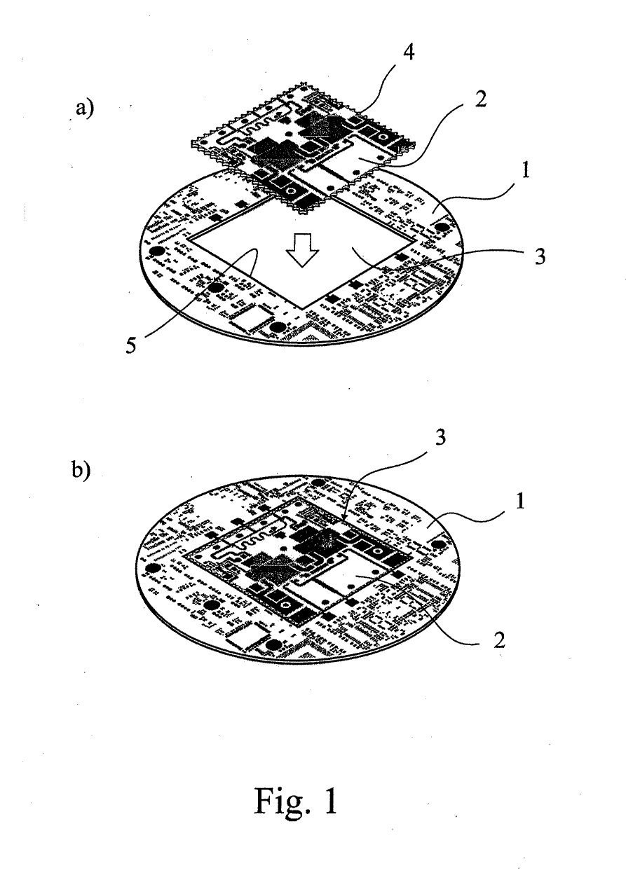

The circuit board system shown in FIG. 1 is equipped with an essentially planar carrier circuit board 1 and an essentially planar circuit board module 2 which, in the assembled state according to FIG. 1b), is inserted into an associated recess 3 in the carrier circuit board 1.

In the present text, the formulation “essentially planar” means that the carrier circuit board 1 and the circuit board module 2 do not have to be plane in the ideal sense. Instead, it means that the carrier circuit board 1 and the circuit board module 2 in each case extend along a plane. In principle, it can also be provided that the carrier circuit board 1 and the circuit board module 2 are essentially designed to be plane only in sections.

Both the carrier circuit board 1 and the circuit board module 2 are in each case fitted with at least one rigid layer copper clad on one or both sides or provided with conductor tracks. This at least one layer consists preferably of a fibreglass-reinforced cured epoxy resin plate of ceramics or the like.

In the assembled state, the circuit board module 2 is aligned in parallel with the carrier circuit board 1 as can be seen in the representation according to FIG. 1b).

It may be pointed out that the carrier circuit board 1 can accommodate an arbitrary number of circuit board modules 2, a corresponding recess 3 being associated with each circuit board module 2 in the carrier circuit board 1. In the text which follows, a single circuit board module 2 and a single recess 3 associated with the circuit board module 2 is always mentioned in the sense of a clear representation. All statements relating to this circuit board module 2 apply correspondingly to all possibly provided further circuit board modules.

It is essential that the circuit board module 2 is pressed into the recess 3 in the carrier circuit board 1 and that the edge 4 of the circuit board module 2 is engaged in a friction-locked manner with the edge 5 of the associated recess 3 to form a press fit.

Pressing the circuit board module 2 into the recess 3 in the carrier circuit board 1 is carried out at an appropriate time within the production process. It is conceivable that the pressing-in is done at the end of the production process when the carrier circuit board 1 and the circuit board module 2 are in each case completed by themselves. However, it is also possible that the carrier circuit board 1 and the circuit board module 2 are joined together in an intermediate production step. The carrier circuit board 1 and the circuit board module 2 then pass through further process stages together. These process stages can be soldering stages, metalizing stages or the like.

The recess 3 is here and preferably as shown in Figure la) a continuous recess, that is to say around an opening within the carrier circuit board 1. The assembled circuit board module 2 is correspondingly accessible from both sides of the carrier circuit board 1.

In the present case, the fact is of special significance that the frictional connection causing the press fit is essentially aligned in parallel with the plane of the carrier circuit board 1. In this arrangement, fixing the circuit board module 2 is partially based on a plastic deformation of the carrier circuit board 1 and of the circuit board module 2, partially on a positive lock between carrier circuit board 1 and circuit board module 2 and partially on friction between carrier circuit board 1 and circuit board module 2.

In a particularly preferred embodiment, the arrangement is made in such a manner that the fixing is essentially based exclusively on the press fit of the circuit board module 2.

In the embodiment shown in FIG. 1b) and preferred to this extent, the circuit board module 2 is engaged in a completely positively locked manner with the associated recess 3. However, it is also conceivable that this positive lock only extends over a section of the circuit board module 2.

The representation according to Figure lb) also shows that the circuit board module 2 and the carrier circuit board 1 are essentially arranged in one plane, wherein the circuit board module 2 and the carrier circuit board 1 preferably end flush. In this case, and preferably, it is even such that the circuit board module 2 and the carrier circuit board 1 end flush on both sides. It is thus easily possible that a soldering stage is passed, as mentioned above, with the circuit board module 2 assembled.

However, the circuit board module 2 does not need to end flush with the carrier circuit board 1 on both sides. For example, the circuit board module 2 can protrude in a defined measure towards at least one outer side so that simple access to a housing or the like can be provided for with corresponding structural boundary conditions.

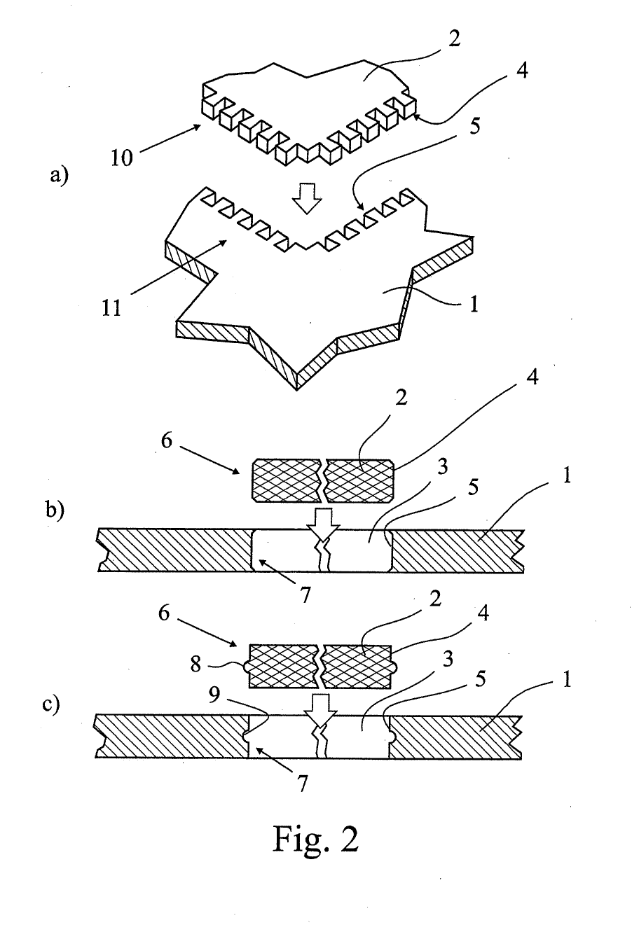

The representations according to FIGS. 2b) and c) show that the cross-sectional profile 6 of the edge 4 of the circuit board module 2 and the cross-sectional profile 7 of the edge 5 of the associated recess 3 are matched to one another to form a positive lock. In this context, it is such in both cases that in each case a convex cross section 6 is associated with a concave cross section 7 to form the positive lock.

In detail, it is such that the cross-sectional profile 6 of the edge 4 of the circuit board module 2 forms a peripheral web 8 whereas the cross-sectional profile 7 of the edge 5 of the associated recess 3 forms a peripheral groove 9. In principle, the association of web 8 and groove 9 can also be provided reversibly. The essential factor is here the fact that clipping the circuit board module 2 into the carrier circuit board 1 is possible with the engagement of web 8 and groove 9 as will still be explained.

The interesting fact in the exemplary embodiment shown in FIG. 2a) is that the outer contour 10 of the edge 4 of the circuit board module 2 and the inner contour 11 of the edge 5 of the associated recess 3 are matched to one another to form a positive lock. Here, and preferably, it is such that the two edges 4 and 5 are interlocked with one another.

Quite generally, the outer contour 10 of the edge 4 of the circuit board module 2 and/or the inner contour 11 of the edge 5 of the associated recess 3 preferably have a periodically repetitive structure, particularly a toothed, serrated or wavy structure. In principle, a positive lock of the type of a swallow tail joint or the like is also conceivable here.

In order to ensure an adequate stability at the edge for the press fit of the circuit board module 2, it is also preferably provided that the edge 4 of the circuit board module 2 and/or the edge 5 of the recess 3 is or are at least partially metalized. In principle, other surface treatments are also conceivable here which, among other things, lead to a hardening of the edge surfaces.

It has already been pointed out that the circuit board system according to the solution according to the proposal can be designed section by section for the respective functional boundary conditions. This can be achieved by the fact that the circuit board module 2 can be designed differently from the carrier circuit board 1 with regard to the material composition and/or surface property and/or layer structure and/or number of layers and/or board thickness. In principle, this makes it possible to achieve more favourable material and production costs, especially if certain functions and tasks are distributed over the respective circuit board modules 2.

Furthermore, the carrier circuit board 1 and the circuit board module 2 can be preproduced separately from one another in an optimized manner and then assembled at the time mentioned above.

The carrier circuit board 1 and the circuit board module 2 can carry out completely different functions. For example, it can be provided that the circuit board module 2 carries out radio-frequency functions, for example the function of a radio-frequency amplifier whereas the carrier circuit board 1 is essentially designed as logic circuit board. This explains that, by means of a suitable selection of circuit board modules 2, a functional modularization of the circuit board system is possible which can contribute to an optimum formation of variants and to considerable cost reduction.

It is also conceivable that the carrier circuit board 1 and/or the circuit board module 2 is or are designed as rigid/flexible circuit board. It is then preferably such that a flexible section of the circuit board module 2 extends over the edge 5 of the associated recess 3 in the carrier circuit board 1. The flexible section of the circuit board module 2 can thus be used as electrical connection of the circuit board module 2 to the carrier circuit board 1.

In a particularly preferred embodiment, it is provided that the electrical contact-connection between the carrier circuit board 1 and the circuit board module 2 is established by inserting the circuit board module 2 into the associated recess 3. It is conceivable, for example, that corresponding electrical contacts protrude over the edge 5 of the recess 3 which are contacted by the circuit board module 2 when it is pressed in. Other advantageous variants for the electrical contact-connection of the circuit board module 2 are conceivable.

In principle, the frictional lock required for the press fit of the circuit board module 2 can be adjusted by the geometric design of the edges 4, 5 of the circuit board module 2 and recess 3. For a more extensive adjustment of the frictional lock, it is preferably provided that the carrier circuit board 1 has at least one elastic area 12 in the area of the recess 3, the elastic restoring force of which acts on the circuit board module 2.

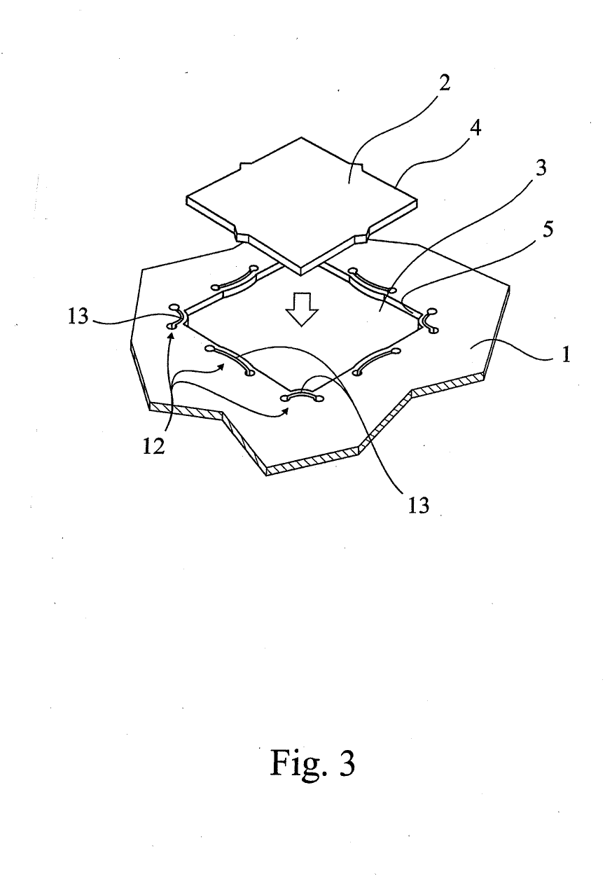

In the exemplary embodiment shown in FIG. 3 and preferred to this extent, the at least one elastic area 12, for increasing the elastic resilience, has a weakening of material 13, which is implemented here and preferably as slot-like recess. However, it is also conceivable that the weakening of material 13 has a through-contact arrangement in the carrier circuit board 1. It has been found in trials that the elastic resilience can be adjusted relatively accurately especially by the selective introduction of through-contact arrangements in the desired elastic area 12.

It has also been pointed out already above that in a particularly preferred embodiment, the fixing of the circuit board module 2 is based exclusively on the press fit of the circuit board module 2. Here, and preferably, it is such that the circuit board module 2 can be removed from the recess 3 by applying a disengaging force and subsequently pressed into the recess 3 again by forming the press fit. This makes it possible to perform maintenance work in a particularly simple manner in that the relative circuit board module 2 is taken out for maintenance. In the case of a repair, the relevant circuit board module 2 can be easily exchanged which can reduce the repair costs quite considerably. For the sake of completeness, however, it must be pointed out that in addition to the press fit, conventional fixing methods can be applied. This includes bonding, soldering, and metalizing of the edge area between circuit board module 2 and carrier circuit board 1.

The solution according to the proposal is also advantageous with regard to the attachment of the circuit board system. It is conceivable here that both the carrier circuit board 1 and the circuit board module 2 can contain openings which are used for attaching the circuit board system. Furthermore, the carrier circuit board 1 and the circuit board module 2 can contain openings which can be used for assembly purposes of components or flat modules.

It is also conceivable that the carrier circuit board 1 and the circuit board module 2 have cavities which can be used for accommodating components, particularly for accommodating uninsulated chips.

Finally, it should be pointed out that the carrier circuit board 1 and the circuit board module 2 can contain integrated elements for heat dissipation, particularly heat sinks.

According to a further teaching which is also accorded independent significance, a method for the assembly of the circuit board system according to the proposal is claimed. It is essential that the circuit board module 2 is pressed into the recess 3 in the carrier circuit board 1 and that, during this process, the edge 4 of the circuit board module 2 is engaged with the edge 5 of the associated recess 3 in a friction-locked manner to form a press fit. To this extent, all the above statements relating to the circuit board system according to the proposal should be referred to.

In a particular preferred embodiment, the circuit board module 2 is clipped into the recess 3 in the carrier circuit board 1. It has already been pointed out that this can ensure an accurate depth to which the circuit board module 2 is pressed into the carrier circuit board 1. This can be implemented by the positive lock in the cross section between circuit board module 2 and carrier circuit board 1 also described above.

What is claimed is:

1. A circuit board system comprising a carrier circuit board which is essentially planar at least in sections, wherein the carrier circuit board has at least one rigid layer copper clad on one or both sides or provided with conductor tracks, wherein at least one essentially planar circuit board module aligned in parallel with the carrier circuit board is arranged with at least one rigid layer copper clad on one or both sides or provided with conductor tracks, in an associated recess in the carrier circuit board, wherein the circuit board module is pressed into the recess in the carrier circuit board and the edge of the circuit board module is engaged in a friction-locked manner with the edge of the associated recess to form a press fit.

2. The circuit board system according to claim 1, wherein the friction lock is essentially aligned in parallel with the plane of the carrier circuit board.

3. The circuit board system according to claim 1, wherein essentially exclusively the press fit holds the circuit board module in the recess in the carrier circuit board.

4. The circuit board system according to claim 1, wherein the circuit board module engages with the associated recess in a friction-locked manner at least in sections.

5. The circuit board system according to claim 1, wherein the circuit board module and the carrier circuit board are arranged essentially in one plane.

6. The circuit board system according to claim 1, wherein the cross-sectional profile of the edge of the circuit board module and the cross-sectional profile of the edge of the associated recess are matched to one another to form a positive lock.

7. The circuit board system according to claim 1, wherein the cross-sectional profile of the edge of the circuit board module, the cross-sectional profile of the edge of the associated recess, or a combination thereof, forms or form at least one peripheral web, at least one peripheral groove, or a combination thereof.

8. The circuit board system according to claim 1, wherein the outer contour of the edge of the circuit board module and the inner contour of the edge of the associated recess are matched to one another to form a positive lock.

9. The circuit board system according to claim 1, wherein the outer contour of the edge of the circuit board module, the inner contour of the edge of the associated recess, or a combination thereof, has or have a periodically repetitive structure.

10. The circuit board system according to claim 1, wherein the edge of the circuit board module, the edge of the recess, or a combination thereof is or are at least partially metalized.

11. The circuit board system according to claim 1, wherein the circuit board module is designed differently from the carrier circuit board with regard to the material composition, surface property, layer structure, number of layers, board thickness, or a combination thereof.

12. The circuit board system according to claim 1, wherein the carrier circuit board, the circuit board module, or a combination thereof is or are designed as rigid/flexible circuit board.

13. The circuit board system according to claim 12, wherein a flexible section of the circuit board module extends over the edge of the associated recess in the carrier circuit board.

14. The circuit board system according to claim 1, wherein an electrical contact-connection between the carrier circuit board and the circuit board module is provided.

15. The circuit board system according to claim 1, wherein the carrier circuit board has at least one elastic area in the area of the recess, the elastic restoring force of which acts on the circuit board module.

16. The circuit board system according to claim 1, wherein the circuit board module can be removed from the recess by applying a disengaging force and subsequently pressed into the recess again by forming the press fit.

17. A method for the assembly of a circuit board system comprising an at least sectionally essentially planar carrier circuit board, wherein the carrier circuit board has at least one rigid layer copper clad on one or both sides or provided with conductor tracks, wherein at least one essentially planar circuit board module aligned in parallel with the carrier circuit board having at least one rigid layer copper clad on one or both sides or provided with conductor tracks is arranged in an associated recess in the carrier circuit board, wherein the circuit board module is pressed into the recess in the carrier circuit board and, during this process, the edge of the circuit board module is engaged with the edge of the associated recess in a friction-locked manner to form a press fit.

18. The method according to claim 17, wherein the circuit board module is clipped into the recess in the carrier circuit board.
